(19) United States
(12) Patent Application Publication
(10) Pub. No.: US 2018/0124918 A1
(43) Pub. Date: May 3, 2018

(54) CIRCUIT BOARD AND CIRCUIT BOARD COMBINATION

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: WEN-HSIANG HUNG, New Taipei (TW); CHUN-BAO GU, Wuhan (CN); CHING-JOU CHEN, New Taipei (TW)

(21) Appl. No.: 15/394,845

(22) Filed: Dec. 30, 2016

(30) Foreign Application Priority Data
Oct. 31, 2016 (CN) 201610939519.5

(51) Int. Cl. H05K 1/11; G06F 1/18; H05K 1/18

(52) U.S. Cl. CPC H05K 1/117; G06F 1/184; H05K 2201/10189; H05K 1/181; H05K 2201/09063; G06F 1/186

(57) ABSTRACT

A circuit board combination includes a circuit board and a control chip. The circuit board includes first and second edges. The circuit board is provided with a first interface module close to the first edge and a second interface module which is close to the second edge. The first interface module is electrically connected with the control chip by a first wire, and the second interface module is electrically connected with the control chip by a second wire, the respective lengths of the first and second wires being equal.

### CROSS-REFERENCE TO RELATED APPLICATIONS

This application claims priority to Chinese Patent Application No. 201610939519.5 filed on Oct. 31, 2016 the contents of which, are incorporated by reference herein.

### FIELD

The subject matter herein generally relates to a circuit board and a circuit board combination.

### BACKGROUND

The motherboard provides the layout and interoperability of components in a computer system within a chassis. The motherboard can be a rectangular circuit board, general having BIOS chip, I/O control chip, keyboard and panel control switch interface, indicator light connectors, expansion slots, and DC power supply connectors, as well as components. In particular, the front and rear sides of the motherboard provides, a number of interfaces for connecting with the I/O control chip.

### BRIEF DESCRIPTION OF THE DRAWINGS

Implementations of the present technology will now be described, by way of example only, with reference to the attached figure.

FIG. 1 is an isometric view of an exemplary embodiment of an assembled circuit board combination.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details.

In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the exemplary embodiments described herein.

Several definitions that apply throughout this disclosure will now be presented.

The term “outside” refers to a region that is beyond the outermost confines of a physical object. The term “inside” indicates that at least a portion of an object is contained within a boundary formed by an object. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series, and the like.

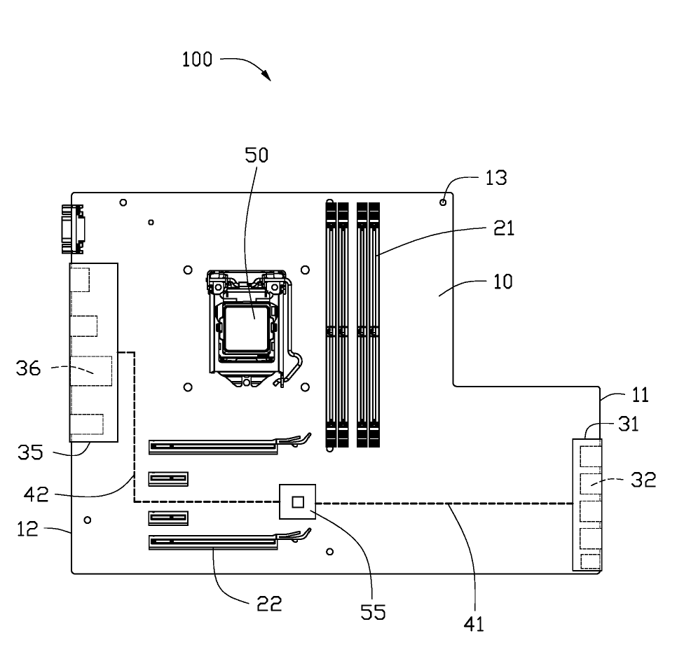

FIG. 1 illustrates one exemplary embodiment of a circuit board combination 100 which includes a circuit board 10, a plurality of electronic components 50, and a plurality of connectors for expansion boards (not shown). In at least one exemplary embodiment, the circuit board 10 can be a motherboard. The electronic components 50 include, but are not limited to, a central processing unit (CPU), a graphics processing unit (GPU), a connector, and the like.

The circuit board 10 includes a first edge 11 and a second edge 12 opposite to the first edge 11. The first edge 11 is substantially parallel to the second edge 12. A plurality of securing holes 13 are defined around the circuit board 10. A plurality of securing members (not shown) can pass through the securing holes 13 to secure the circuit board 10 on a chassis (not shown). The circuit board 10 further defines a plurality of first slots 21 and a plurality of second slots 22. The first slots 21 and the second slots 22 are configured to connect to various types of expansion cards.

The circuit board 10 includes a first interface module 31 at the first edge 11. The first interface module 31 includes a plurality of first interfaces 32. The first interface module 31 is configured to electrically connect with other electronic devices. The circuit board 10 includes a second interface module 35 at the second edge 12. The second interface module 35 includes a plurality of second interfaces 36. The plurality of second interfaces 36 is configured to electrically connect to other electronic devices.

In at least one exemplary embodiment, the first interfaces 32 and the second interfaces 36 include any one or more of a USB interface, a HDMI interface, a VGA interface, and a DVI interface. Other electronic devices include a keyboard, a mouse, an earphone, an external hard disk, and the like.

The electronic components 50 include a control chip 55. The control chip 55 is configured to receive and transmit signals to control the first interface module 31 and the second interface module 35. The control chip 55 is electrically connected with the first interface module 31 by a first wire 41 and is electrically connected with the second interface module 32 by a second wire 42.

The length of the first wire 41 is substantially equal to the length of the second wire 42, and the control chip 55 transmits signals between the control chip 55 and the first interface module 31 and the second interface module 36. In at least one exemplary embodiment, the first wire 41 and the second wire 42 is designed into the circuit board. In at least one exemplary embodiment, the control chip 55 can be a southbridge chip.

The exemplary embodiments shown and described above are only examples. Many details are often found in the art such as the other features of a circuit board combination. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A circuit board comprising:
a first edge;
a first interface module near a periphery of the first edge;
a second edge opposite to the first edge; and
a second interface module near a periphery of the second edge;
wherein the first interface module is electrically connected with a control chip by a first wire, the second interface module is electrically connected with the control chip by a second wire, and the length of the first wire is equal to the length of the second wire.

2. The circuit board of claim 1, wherein the first interface module comprises a plurality of first interfaces, and the plurality of first interfaces is configured to electrically connect to other electronic devices.

3. The circuit board of claim 2, wherein the second interface module comprises a plurality of second interfaces, and the plurality of second interfaces is configured to electrically connect to other electronic devices.

4. The circuit board of claim 1, wherein the control chip is a southbridge chip.

5. The circuit board of claim 3, wherein the first interfaces and the second interfaces comprise a combination of any one or more of a USB interface, a HDMI interface, a VGA interface, and a DVI interface.

6. The circuit board of claim 1, wherein a plurality of securing holes is defined around the circuit board, and a plurality of securing members pass through the securing holes to secure the circuit board on a chassis.

7. The circuit board of claim 1, wherein the circuit board further comprises a plurality of first slots and a plurality of second slots, and the first slots and the second slots are used to connect different type of expansion cards.

8. A circuit board combination, comprising:
a circuit board comprising:
a first edge;
a first interface module near a periphery of the first edge;
a second edge opposite to the first edge; and
a second interface module near a periphery of the second edge;
a control chip secured on the circuit board;
wherein the first interface module is electrically connected with the control chip by a first wire, the second interface module is electrically connected with the control chip by a second wire, and the length of the first wire is equal to the length of the second wire.

9. The circuit board combination of claim 8, wherein the first interface module comprises a plurality of first interfaces, and the plurality of first interfaces is configured to electrically connect to other electronic devices.

10. The circuit board combination of claim 9, wherein the second interface module comprises a plurality of second interfaces, and the plurality of second interfaces is configured to electrically connect to other electronic devices.

11. The circuit board combination of claim 8, wherein the control chip is a southbridge chip.

12. The circuit board combination of claim 10, wherein the first interfaces and the second interfaces comprise a combination of any one or more of a USB interface, a HDMI interface, a VGA interface, and a DVI interface.

13. The circuit board combination of claim 1, wherein a plurality of securing holes is defined around the circuit board, and a plurality of securing members pass through the securing holes to secure the circuit board on a chassis.

14. The circuit board of combination claim 1, wherein the circuit board further comprises a plurality of first slots and a plurality of second slots, and the first slots and the second slots are used to connect different type of expansion cards.
